(19) United States
(12) Patent Application Publication
(10) Pub. No.: US 2024/0222932 A1
(43) Pub. Date: Jul. 4, 2024

(54) DRIVE CIRCUIT, LIGHT SOURCE DEVICE, AND DELAY CIRCUIT

(71) Applicant: Sony Semiconductor Solutions Corporation, Kanagawa (JP)

(72) Inventor: Shouichi Kuroki, Kagoshima (JP)

(21) Appl. No.: 18/558,072

(22) PCT Filed: Feb. 14, 2022
(86) PCT No.: PCT/JP2022/005557

§ 371 Date: Oct. 30, 2023

(30) Foreign Application Priority Data
Jun. 10, 2021 (JP) 2021-097254

(51) Int. Cl. H01S 5/062; G01S 7/484

(52) U.S. Cl. CPC H01S 5/062; G01S 7/484

(57) ABSTRACT

A delay in light application of a plurality of light emitting elements is adjusted. A drive circuit includes a plurality of row drive signal delay units, a plurality of column drive signal delay units, a plurality of row light emission drive units, a plurality of column light emission drive units, a row delay adjustment unit, and a column delay adjustment unit. The row drive signal delay units are arranged for respective rows in a light emitting element array unit configured by arranging, in the form of a two-dimensional matrix, a plurality of light emitting elements emitting light by a flow of a light emission current, and output a row drive signal obtained by delaying a light emission drive signal for controlling light emission of the light emitting element. The column drive signal delay units are arranged for respective columns in the light emitting element array unit, and output a column drive signal obtained by delaying the light emission drive signal. The row delay adjustment unit adjusts a delay time in the plurality of row drive signal delay units. The column delay adjustment unit adjusts a delay time in the plurality of column drive signal delay units.

### FIELD

The present disclosure relates to a drive circuit, a light source device, and a delay circuit.

### BACKGROUND

In measuring a distance to an object, a distance measuring device is used which measures the distance to the object by applying light to the object and measuring a reciprocation time of the applied light to and from the object. In such a distance measuring device, a light source device that applies light to an object or the like is required. As this light source device, for example, a light source device that includes a light source such as a laser light source and performs light application at a predetermined timing is used. In the distance measuring device, the start of application in the light source device and the start of counting a reciprocation time of light are performed in synchronization. Specifically, in synchronization with an output of a control signal indicating the application of light in the light source device to the light source device, counting of the reciprocation time is started. Usually, a delay occurs from an input of the control signal to light application. In order to reduce an error in distance measurement, counting of the reciprocation time is performed in consideration of this delay.

In such a light source device, a light source device in which a plurality of light sources is arranged has been proposed in order to increase the amount of light applied to an object. For example, a spatial information detection device including a light projecting circuit portion configured by arranging a light emitting element group including a plurality of light emitting elements and a plurality of energization control elements for energizing the light emitting element group has been proposed (see, for example, Patent Literature 1).

In this spatial information detection device, a rectangular wave signal having a constant period is used as a modulation signal. The energization control element is controlled by this modulation signal to cause the light emitting element group to emit light, and intensity-modulated light is extracted. Reflected light obtained by reflecting this intensity-modulated light by the object is received by a light receiving circuit having a light receiving element, and a demodulation signal synchronized with the modulation signal is generated. By detecting a phase difference between this generated demodulation signal and the modulation signal, a time until the intensity-modulated light projected from the light emitting element to a target space is received by the light receiving element is measured.

In addition, this spatial information detection device extracts a signal of a connection point between one light emitting element group of the plurality of light emitting element groups and the energization control element as a detection signal. By adjusting a time difference between this detection signal and the demodulation signal, a delay in light emission in the light emitting element is compensated.

### CITATION LIST

### Patent Literature

Patent Literature 1: JP 2013-064647 A

### SUMMARY

### Technical Problem

However, in the above-described conventional technology, since a delay of the entire light emitting element group is compensated by the detection signal of one light emitting element group of the plurality of light emitting element groups, there is a problem that a delay time of the plurality of light emitting element groups cannot be adjusted. Therefore, there is a problem that light emission of the plurality of light emitting element groups varies and an error in distance measurement increases.

Therefore, the present disclosure proposes a light source device that adjusts a delay in light application of a plurality of light emitting elements.

### Solution to Problem

A drive circuit according to the present disclosure includes: a plurality of row drive signal delay units arranged for respective rows in a light emitting element array unit, the light emitting element array unit being configured by arranging a plurality of light emitting elements in a form of a two-dimensional matrix, the plurality of light emitting elements emitting light by a flow of a light emission current, the plurality of row drive signal delay units outputting a row drive signal obtained by delaying a light emission drive signal for controlling light emission of the light emitting element; a plurality of column drive signal delay units arranged for respective columns in the light emitting element array unit, the plurality of column drive signal delay units outputting a column drive signal obtained by delaying the light emission drive signal; a plurality of row light emission drive units arranged for the respective rows in the light emitting element array unit, the plurality of row light emission drive units supplying, on a basis of the row drive signal output by the row drive signal delay unit arranged for the row, the light emission current as a source current to a plurality of the light emitting elements arranged in the row; a plurality of column light emission drive units arranged for the respective columns in the light emitting element array unit, the plurality of column light emission drive units supplying, on a basis of the column drive signal output by the column drive signal delay unit arranged for the column, the light emission current as a sink current to a plurality of the light emitting elements arranged in the column; a row delay adjustment unit adjusting a delay time in the plurality of row drive signal delay units; and a column delay adjustment unit adjusting a delay time in the plurality of column drive signal delay units.

### BRIEF DESCRIPTION OF DRAWINGS

FIG. 1 is a diagram illustrating a configuration example of a light source device according to a first embodiment of the present disclosure.

FIG. 2 is a diagram illustrating a configuration example of a light emitting element array unit according to the embodiment of the present disclosure.

FIG. 3 is a diagram illustrating a configuration example of a row drive unit according to the embodiment of the present disclosure.

FIG. 4 is a diagram illustrating a configuration example of a column drive unit according to the embodiment of the present disclosure.

FIG. 5 is a diagram illustrating a configuration example of a row drive signal delay unit according to the embodiment of the present disclosure.

FIG. 6 is a diagram illustrating another configuration example of the row drive signal delay unit according to the embodiment of the present disclosure.

FIG. 7 is a diagram illustrating an example of a method of driving the light emitting element array unit according to the embodiment of the present disclosure.

FIG. 8 is a diagram illustrating a configuration example of a light source device according to a second embodiment of the present disclosure.

FIG. 9 is a diagram illustrating a configuration example of an imaging device to which the technology according to the present disclosure can be applied.

### DESCRIPTION OF EMBODIMENTS

Hereinafter, embodiments of the present disclosure will be described in detail with reference to the drawings. The description will be given in the following order. Note that in the following embodiments, the same parts are denoted by the same reference numerals, and redundant description will be omitted.
1. First Embodiment
2. Second Embodiment
3. Configuration Example of Imaging Device

### 1. First Embodiment

### [Configuration of Light Source Device]

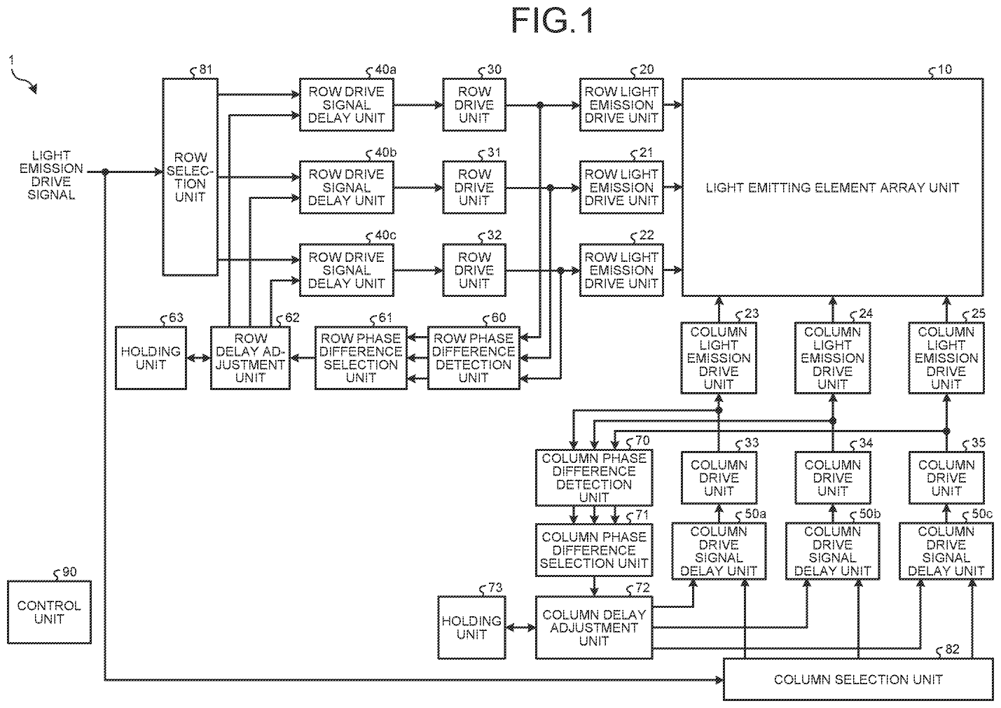

FIG. 1 is a diagram illustrating a configuration example of a light source device according to a first embodiment of the present disclosure. The drawing is a block diagram representing a configuration example of a light source device 1. The light source device 1 is a device that applies light to an object. This light source device 1 is used in a distance measuring device or the like that measures a distance to an object, and applies light to the object at a predetermined timing.

The light source device 1 includes a light emitting element array unit 10, row light emission drive units 20 to 22, row drive units 30 to 32, a row drive signal delay unit 40, a row phase difference detection unit 60, a row phase difference selection unit 61, a row delay adjustment unit 62, a holding unit 63, and a row selection unit 81. In addition, the light source device 1 further includes column light emission drive units 23 to 25, column drive units 33 to 35, a column drive signal delay unit 50, a column phase difference detection unit 70, a column phase difference selection unit 71, a column delay adjustment unit 72, a holding unit 73, a column selection unit 82, and a control unit 90.

The light source device 1 in the drawing performs application of light on the basis of a light emission drive signal input from a distance measuring device or the like. This light emission drive signal is, for example, a digital signal, and a value “1” and a value “0” are signals respectively representing light emission and non-light emission. In addition, this light emission drive signal can be supplied via, for example, a differential transmission line. As an interface of this differential transmission line, for example, low voltage differential signaling (LVDS) can be adopted. Note that illustration of a receiving unit and the like of an LVDS signal is omitted in the drawing.

The light emitting element array unit 10 is configured by arranging a plurality of light emitting elements (light emitting elements 11 to be described later) in the form of a two-dimensional matrix. As the light emitting element 11, an element that emits light by the flow of a current, for example, a laser diode can be used. This laser diode is an element having two terminals of an anode and a cathode, and emits light by the flow of a current from the anode to the cathode. Note that a current that causes the light emitting element 11 to emit light is referred to as a light emission current. The light emitting element array unit 10 in the drawing represents an example in which the light emitting elements are arranged in three rows and three columns. Details of a configuration of the light emitting element array unit 10 will be described later.

The row light emission drive units 20 to 22 are arranged for respective rows of the light emitting element array unit 10, and supply the light emission current to the plurality of light emitting elements 11 arranged in the row of the light emitting element array unit 10. The row light emission drive units 20 to 22 are each connected to one terminal, for example an anode, of the two terminals of the light emitting element 11 arranged in the row of the light emitting element array unit 10. In this case, the row light emission drive units 20 to 22 supply a source current as the light emission current. Details of a configuration of the row light emission drive units 20 to 22 will be described later.

The column light emission drive units 23 to 25 are arranged for respective columns of the light emitting element array unit 10, and supply the light emission current to the plurality of light emitting elements 11 arranged in the column of the light emitting element array unit 10. The column light emission drive units 23 to 25 are each connected to a terminal, on a side to which the row light emission drive units 20 and the like are not connected, of the two terminals of the light emitting element 11 arranged in the column of the light emitting element array unit 10. In this case, the column light emission drive units 23 to 25 are each connected to a cathode of the light emitting element 11, and supply a sink current as the light emission current. Details of a configuration of the column light emission drive units 23 to 25 will be described later.

The row selection unit 81 selects a row in which light emission is to be caused in a plurality of the rows of the light emitting element array unit 10. This row selection unit 81 selects a row of the light emitting element array unit 10 on the basis of control of the control unit 90, and transmits a light emission drive signal to the row light emission drive units 20 to 22 corresponding to the selected row.

The row drive signal delay unit 40 delays the light emission drive signal transmitted for each row of the light emitting element array unit 10. In the drawing, row drive signal delay units 40a, 40b, and 40c are arranged corresponding to the respective rows of the light emitting element array unit 10, and delay the light emission drive signal input from the row selection unit 81. This light emission drive signal delayed for each row is referred to as a row drive signal. Delay times of these row drive signal delay units 40a, 40b, and 40c are each adjusted on the basis of a control signal from a row delay adjustment unit 62 to be described later. That is, the row drive signal delay unit 40 is a delay circuit capable of changing a delay time on the basis of an external signal.

The row drive units 30 to 32 respectively drive the row light emission drive units 20 to 22. That is, the row drive units 30 and the like are arranged for respective rows of the light emitting element array unit 10. The row drive units 30 to 32 generate a drive signal for the row light emission drive units 20 and the like from the row drive signal output from the row drive signal delay unit 40, and output the drive signal.

The row phase difference detection unit 60 detects a phase difference between the row drive signal and a reference signal. This row phase difference detection unit 60 outputs a signal corresponding to the phase difference as a detection result. The row phase difference detection unit 60 in the drawing represents an example of detecting a phase difference from the reference signal for each of the row drive units 30 to 32. The detection results are each output to the row phase difference selection unit 61.

The row phase difference selection unit 61 selects one of the detection results of the phase difference for each row by the row phase difference detection unit 60. This row phase difference selection unit 61 outputs the selected detection result to the row delay adjustment unit 62.

The row delay adjustment unit 62 adjusts a delay of the row drive signal delay unit 40. The row delay adjustment unit 62 in the drawing adjusts the delays of the row drive signal delay units 40a, 40b, and 40c arranged for the respective rows. Specifically, the row delay adjustment unit 62 adjusts, on the basis of the detection result of the phase difference in the row selected by the row phase difference selection unit 61 described above, the delay of the row drive signal delay units 40a, 40b, and 40c arranged for the row.

As described above, the light emitting elements 11 of the light emitting element array unit 10 are driven by the row light emission drive units 20 to 22 for the respective rows. That is, the light emitting elements 11 in the respective rows of the light emitting element array unit 10 are individually driven respectively by the row drive unit 30 and the row light emission drive unit 20, the row drive unit 31 and the row light emission drive unit 21, and the row drive unit 32 and the row light emission drive unit 22. A delay time from when the light emission drive signal is input to the row drive unit 30 or the like to when the light emitting elements 11 in the corresponding row of the light emitting element array unit 10 emit light varies depending on the row drive unit 30 or the like and the row light emission drive unit 20 or the like. Therefore, the light emission of the light emitting elements 11 varies for each row of the light emitting element array unit 10, which causes an error in distance measurement.

Therefore, the row delay adjustment unit 62 adjusts the delay for each row to reduce the variation. The row delay adjustment unit 62 adjusts the delay by outputting a control signal indicating a delay to the row drive signal delay units 40a, 40b, and 40c. As this control signal, a digital signal having a predetermined bit width can be used. For example, the delay time can be made to correspond to the number of bits of the value “1” of the control signal. In addition, the row delay adjustment unit 62 causes the holding unit 63 to be described later to hold information on the adjusted delay. In addition, at the time of activation of the light source device 1, the row delay adjustment unit 62 reads the delay information from the holding unit 63, outputs the delay information to the row drive signal delay units 40a, 40b, and 40c, and sets a delay time for each row.

The holding unit 63 holds delay information for each row. This holding unit 63 can adopt, for example, a configuration in which the holding unit 63 holds, as delay information, the digital control signal output by the row delay adjustment unit 62.

The column selection unit 82 selects a column in which light emission is to be caused in a plurality of the columns of the light emitting element array unit 10. This column selection unit 82 selects a column of the light emitting element array unit 10 on the basis of control of the control unit 90, and transmits the light emission drive signal to the column light emission drive units 23 to 25 corresponding to the selected column.

The column drive signal delay unit 50 delays the light emission drive signal transmitted for each column of the light emitting element array unit 10. In the drawing, column drive signal delay units 50a, 50b, and 50c are arranged corresponding to the respective columns of the light emitting element array unit 10, and delay the light emission drive signal input from the column selection unit 82. This light emission drive signal delayed for each column is referred to as a column drive signal. Delay times of these column drive signal delay units 50a, 50b, and 50c are each adjusted on the basis of a control signal from the column delay adjustment unit 72 to be described later. That is, similarly to the row drive signal delay unit 40, the column drive signal delay unit 50 is a delay circuit capable of changing a delay time on the basis of an external signal.

The column drive units 33 to 35 respectively drive the column light emission drive units 23 to 25. That is, the column drive units 33 and the like are arranged for respective columns of the light emitting element array unit 10. The column drive units 33 to 35 generate a drive signal for the column light emission drive units 23 and the like from the column drive signal output from the column drive signal delay unit 50, and output the drive signal.

The column phase difference detection unit 70 detects a phase difference between the column drive signal and the reference signal. Similarly to the row phase difference detection unit 60, the column phase difference detection unit 70 outputs a signal corresponding to the phase difference as a detection result. The column phase difference detection unit 70 in the drawing represents an example of detecting a phase difference from the reference signal for each of the column drive units 33 to 35. The detection results are each output to the column phase difference selection unit 71.

The column phase difference selection unit 71 selects one of the detection results of the phase difference for each column of the column phase difference detection unit 70. This column phase difference selection unit 71 outputs the selected detection result to the column delay adjustment unit 72.

The column delay adjustment unit 72 adjusts the delay of the column drive signal delay unit 50. The column delay adjustment unit 72 in the drawing adjusts the delays of the column drive signal delay units 50a, 50b, and 50c arranged for the respective columns. Specifically, the column delay adjustment unit 72 adjusts, on the basis of the detection result of the phase difference in the column selected by the column phase difference selection unit 71 described above, the delay of the column drive signal delay units 50a, 50b, and 50c arranged for the column.

As described above, the light emitting elements 11 of the light emitting element array unit 10 are driven by the column light emission drive units 23 to 25 for the respective columns. That is, the light emitting elements 11 in the respective columns of the light emitting element array unit 10 are individually driven respectively by the column drive unit 33 and the column light emission drive unit 23, the column drive unit 34 and the column light emission drive unit 24, and the column drive unit 35 and the column light emission drive unit 25. A delay time from when the light emission drive signal is input to the column drive unit 33 or the like to when the light emitting elements 11 in the corresponding column of the light emitting element array unit 10 emit light varies depending on the column drive unit 33 or the like and the column light emission drive unit 23 or the like. Therefore, the light emission of the light emitting elements 11 varies for each column of the light emitting element array unit 10, which causes an error in distance measurement.

Similarly to the row delay adjustment unit 62, the column delay adjustment unit 72 adjusts the delay for each column. That is, the column delay adjustment unit 72 reduces variations in delay among the column drive unit 33 and the column light emission drive unit 23, the column drive unit 34 and the column light emission drive unit 24, and the column drive unit 35 and the column light emission drive unit 25. The column delay adjustment unit 72 adjusts the delay by outputting a control signal indicating a delay to the column drive signal delay units 50a, 50b, and 50c. Similarly to the row delay adjustment unit 62, a digital signal having a predetermined bit width can be used as this control signal, and the delay time can be made to correspond to the number of bits of the value “1” of the control signal. In addition, the column delay adjustment unit 72 causes the holding unit 73 to be described later to hold information on the adjusted delay. In addition, at the time of activation of the light source device 1, the column delay adjustment unit 72 reads the delay information from the holding unit 73, outputs the delay information to the column drive signal delay units 50a, 50b, and 50c, and sets a delay time for each column.

The holding unit 73 holds delay information for each column. Similarly to the holding unit 63, the holding unit 73 can adopt a configuration in which the holding unit 73 holds, as delay information, the digital control signal output by the column delay adjustment unit 72.

The control unit 90 controls the whole of the light source device 1. This control unit 90 outputs control signals to the row selection unit 81, the row delay adjustment unit 62, the row phase difference selection unit 61, the column selection unit 82, the column delay adjustment unit 72, and the column phase difference selection unit 71 to perform control.

### [Configuration of Light Emitting Element Array Unit]

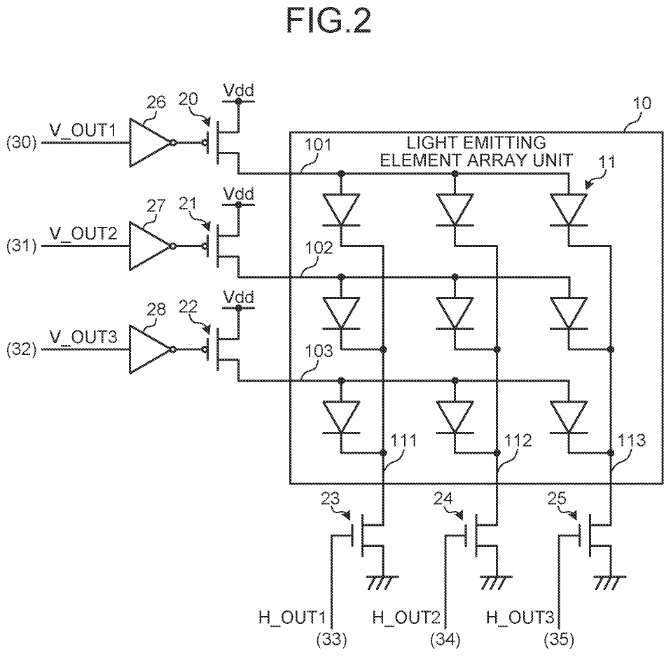

FIG. 2 is a diagram illustrating a configuration example of a light emitting element array unit according to the embodiment of the present disclosure. The drawing is a circuit diagram representing a configuration example of the light emitting element array unit 10. In addition, the row light emission drive units 20 to 22 and the column light emission drive units 23 to 25 are further illustrated in the drawing.

As described above, the light emitting element array unit 10 is configured by arranging the light emitting elements 11 in the form of a two-dimensional matrix. The light emitting element array unit 10 in the drawing represents an example in which the light emitting elements 11 are arranged in three rows and three columns. In addition, in the light emitting element array unit 10, a wiring through which the light emission current flows to the light emitting element 11 is arranged for each row and column. In the light emitting element array unit 10 in the drawing, wirings 101 to 103 and wirings 111 to 113 are arranged. The wirings 101 to 103 are arranged in the rows of the light emitting element array unit 10, and the anodes of the plurality of light emitting elements 11 arranged in each of the rows are commonly connected. The wirings 111 to 113 are arranged in the columns of the light emitting element array unit 10, and the cathodes of the plurality of light emitting elements 11 arranged in each of the columns are commonly connected.

The row light emission drive units 20 to 22 are arranged for the respective rows of the light emitting element array unit 10. The row light emission drive units 20 to 22 in the drawing represent an example of including p-channel MOS transistors. The drive signals from the row drive units 30 to 32 described in FIG. 1 are respectively input to the row light emission drive units 20 to 22 via a signal line V_OUT1, a signal line V_OUT2, and a signal line V_OUT3. Sources of the row light emission drive units 20 to 22 are connected to a power supply line Vdd, and drains thereof are respectively connected to the wirings 101 to 103. A gate of the row light emission drive unit 20 is connected to the signal line V_OUT1 via an inverting buffer 26. A gate of the row light emission drive unit 21 is connected to the signal line V_OUT2 via an inverting buffer 27. A gate of the row light emission drive unit 22 is connected to the signal line V_OUT3 via an inverting buffer 28.

The column light emission drive units 23 to 25 are arranged for the respective columns of the light emitting element array unit 10. The column light emission drive units 23 to 25 in the drawing represent an example in which the column light emission drive units 23 to 25 include n-channel MOS transistors. The drive signals from the column drive units 33 to 35 described in FIG. 1 are respectively input to the column light emission drive units 23 to 25 via a signal line H_OUT1, a signal line H_OUT2, and a signal line H_OUT3. Sources of the column light emission drive units 23 to 25 are grounded, and drains thereof are respectively connected to the wirings 111 to 113. Gates of the column light emission drive units 23 to 25 are respectively connected to the signal line H_OUT1, the signal line H_OUT2, and the signal line H_OUT3.

In order to cause the light emitting element 11 of the light emitting element array unit 10 to emit light, the row light emission drive units 20 to 22 and the column light emission drive units 23 to 25 connected to the light emitting element 11 are conducted. As a result, the light emission current from the power supply line Vdd flows to the light emitting element 11 to cause light emission. At this time, the row light emission drive units 20 to 22 supply the light emission current as a source current to the anode of the light emitting element 11, and the column light emission drive units 23 to 25 supply the light emission current as a sink current to the cathode of the light emitting element 11.

By conducting one or more of the row light emission drive units 20 to 22 and one or more of the column light emission drive units 23 to 25, any light emitting element 11 of the light emitting element array unit 10 can be caused to emit light.

### [Configuration of Row Drive Unit]

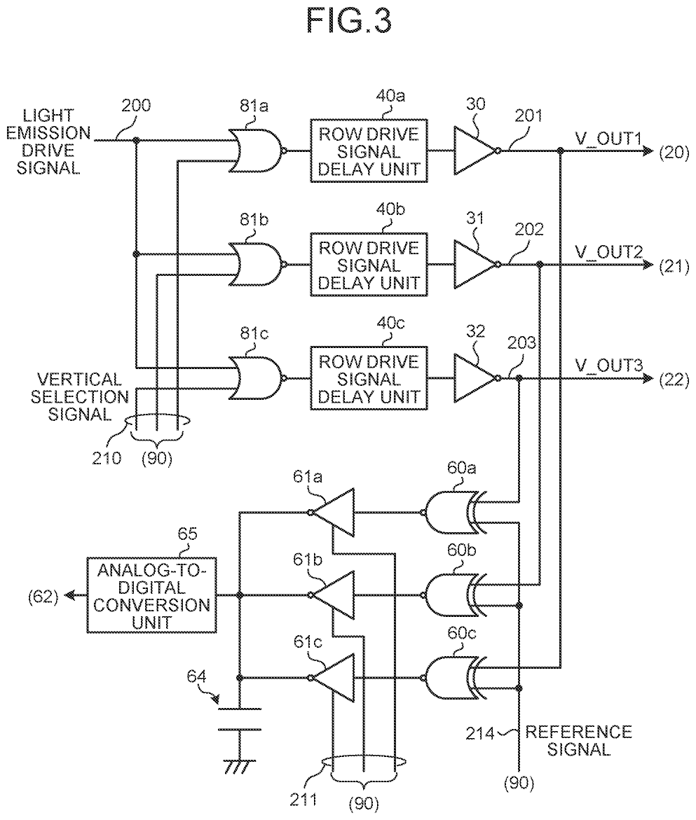

FIG. 3 is a diagram illustrating a configuration example of a row drive unit according to the embodiment of the present disclosure. The drawing is a diagram representing a configuration example of the row drive units 30 to 32, the row drive signal delay unit 40, the row phase difference detection unit 60, the row selection unit 81, and the row phase difference selection unit 61.

In the drawing, the row selection unit 81 includes row selection units 81a, 81b, and 81c including two-input NOR gates. In addition, a signal line 210 is connected to the row selection unit 81. This signal line 210 includes three signal lines, each of which transmits a vertical selection signal from the control unit 90. A signal line 200 is commonly connected to one input terminals of the row selection units 81a, 81b, and 81c. This signal line 200 is a signal line that transmits the light emission drive signal. The signal lines 210 are individually connected to the other input terminals of the row selection units 81a, 81b, and 81c. Output terminals of the row selection units 81a, 81b, and 81c are respectively connected to the row drive signal delay units 40a, 40b, and 40c.

As the vertical selection signal, a signal having the value “0” can be used. The control unit 90 outputs the vertical selection signal having the value “0” to the row selection units 81a, 81b, and 81c for a row to be selected, and outputs the value “1” to the row selection units 81a, 81b, and 81c for a row not to be selected. The row selection units 81a, 81b, and 81c to which this vertical selection signal is input transmit the light emission drive signal to the row drive signal delay units 40a and the like. As a result, a row of the light emitting element array unit 10 can be selected.

As described above, the light emission drive signals selected by the row selection units 81a, 81b, and 81c are input to the row drive signal delay units 40a, 40b, and 40c. This input light emission drive signal is delayed by the row drive signal delay units 40a, 40b, and 40c to become a row drive signal, and is output to the row drive units 30 to 32.

The row drive units 30 to 32 in the drawing represent an example of including inverting buffers. Inputs of the row drive units 30 to 32 are respectively connected to outputs of the row drive signal delay units 40a, 40b, and 40c. Outputs of the row drive units 30 to 32 are respectively connected to the signal line V_OUT1, the signal line V_OUT2, and the signal line V_OUT3. The row drive units 30 to 32 generate a drive signal for the row light emission drive units 20 and the like on the basis of the row drive signal input by the row drive signal delay units 40a, 40b, and 40c, and output the drive signal to the signal lines V_OUT1 and the like.

In the drawing, the row phase difference detection unit 60 includes row phase difference detection units 60a, 60b, and 60c including two-input XNOR gates. In addition, a signal line 214 is connected to the row phase difference detection unit 60. This signal line 214 transmits the reference signal from the control unit 90. This reference signal is a signal serving as a reference for phase difference detection in the row phase difference detection unit 60. The signal line 214 is commonly connected to one input terminals of the row phase difference detection units 60a, 60b, and 60c. The signal line V_OUT1, the signal line V_OUT2, and the signal line V_OUT3 are respectively connected to the other input terminals of the row phase difference detection units 60a, 60b, and 60c. A phase difference between the row drive signal and the reference signal is detected for each row by the row phase difference detection units 60a, 60b, and 60c. Output terminals of the row phase difference detection units 60a, 60b, and 60c are respectively connected to input terminals of row phase difference selection units 61a, 61b, and 61c to be described later.

In the drawing, the row phase difference selection unit 61 includes the row phase difference selection units 61a, 61b, and 61c including inverting buffers with control input terminals. In addition, these row phase difference selection units 61a, 61b, and 61c are current output-type inverting buffers. In addition, a signal line 211 is connected to the row phase difference selection unit 61. This signal line 211 includes three signal lines, each of which transmits a selection signal from the control unit 90. The signal lines 211 are individually connected to the control input terminals of the row phase difference selection units 61a, 61b, and 61c. As the selection signal, a signal having the value “1” can be used. The control unit 90 outputs the selection signal having the value “1” to the row phase difference selection units 61a, 61b, and 61c for a selected row, and outputs the value “0” to the row phase difference selection units 61a, 61b, and 61c for a non-selected row. The row phase difference selection units 61a, 61b, and 61c to the control input terminal of which the selection signal having the value “1” is input invert the detection result of the row phase difference detection unit 60 and transmit the inverted detection result. On the other hand, the row phase difference selection units 61a, 61b, and 61c to the control input terminal of which the value “0” is input have outputs in a high impedance state. As a result, selection of the detection results of the row phase difference detection unit 60 by the row phase difference selection units 61a, 61b, and 61c is performed.

Output terminals of the row phase difference selection units 61a, 61b, and 61c are commonly connected to one end of a capacitor 64 (not illustrated in FIG. 1) and an input of an analog-to-digital conversion unit 65 (not illustrated in FIG. 1). The other end of the capacitor 64 is grounded. The capacitor 64 is charged and discharged by the selected row phase difference selection units 61a, 61b, and 61c. The row phase difference detection unit 60 described above outputs a pulse wave signal as a detection result of phase difference. The capacitor 64 is charged and discharged according to this output pulse wave, and is averaged. As a result, an analog signal corresponding to the phase difference can be generated. This signal is converted into a digital signal by the analog-to-digital conversion unit 65 and input to the row delay adjustment unit 62. The row delay adjustment unit 62 adjusts the delays of the row drive signal delay units 40a, 40b, and 40c on the basis of the input digital phase difference signal.

### [Configuration of Column Drive Unit]

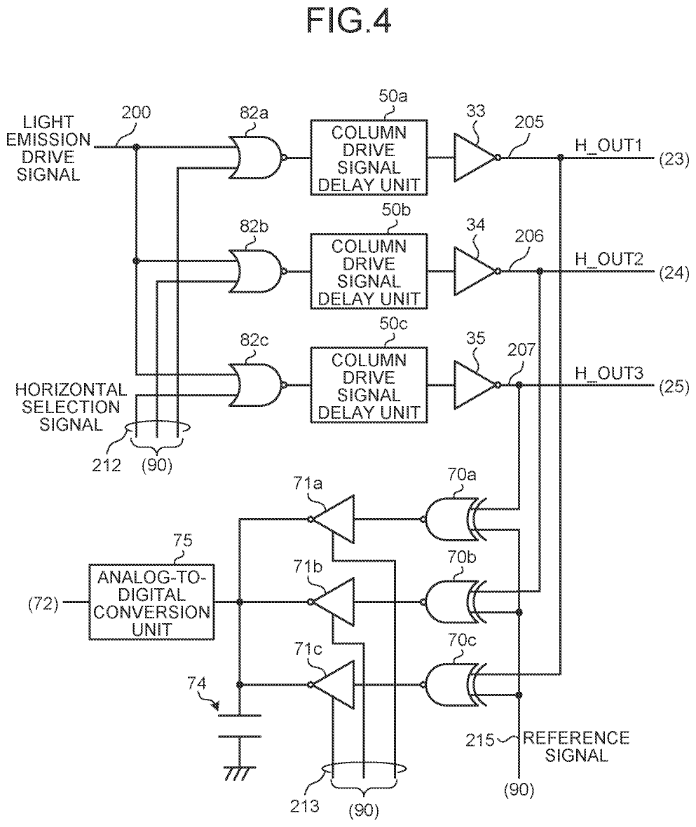

FIG. 4 is a diagram illustrating a configuration example of a column drive unit according to the embodiment of the present disclosure. The drawing is a diagram illustrating a configuration example of the column drive units 33 to 35, the column drive signal delay unit 50, the column phase difference detection unit 70, the column selection unit 82, and the column phase difference selection unit 71.

Similarly to the row selection unit 81, the column selection unit 82 in the drawing includes column selection units 82a, 82b, and 82c including two-input NOR gates. In addition, a signal line 212 is connected to the column selection unit 82. This signal line 212 includes three signal lines, each of which transmits a horizontal selection signal from the control unit 90. The signal line 200 is commonly connected to one input terminals of the column selection units 82a, 82b, and 82c, and the light emission drive signal is input. The signal lines 212 are individually connected to the other input terminals of the column selection units 82a, 82b, and 82c. Output terminals of the column selection units 82a, 82b, and 82c are respectively connected to the column drive signal delay units 50a, 50b, and 50c.

As the horizontal selection signal, a signal having the value “0” can be used similarly to the vertical selection signal. The control unit 90 can select a column of the light emitting element array unit 10 by outputting the vertical selection signal having the value “0” to the column selection units 82a, 82b, and 82c for a column to be selected and outputting the value “1” to the column selection units 82a, 82b, and 82c for a column not to be selected.

The light emission drive signal selected by the column selection units 82a, 82b, and 82c is input to the column drive signal delay units 50a, 50b, and 50c. This input light emission drive signal is delayed by the column drive signal delay units 50a, 50b, and 50c to become a column drive signal, which is output to the column drive units 33 to 35.

Similarly to the row drive units 30 and the like, the column drive units 33 to 35 represent an example of including inverting buffers. Inputs of the column drive units 33 to 35 are respectively connected to outputs of the column drive signal delay units 50a, 50b, and 50c. Outputs of the column drive units 33 to 35 are respectively connected to the signal line H_OUT1, the signal line H_OUT2, and the signal line H_OUT3. The column drive units 33 to 35 generate a drive signal for the column light emission drive units 23 and the like on the basis of the column drive signal input by the column drive signal delay units 50a, 50b, and 50c, and output the drive signal to the signal lines H_OUT1 and the like.

Similarly to the row phase difference detection unit 60, the column phase difference detection unit 70 includes column phase difference detection units 70a, 70b, and 70c including two-input XNOR gates. In addition, a signal line 215 is connected to the column phase difference detection unit 70. This signal line 215 transmits the reference signal from the control unit 90. This reference signal is a signal serving as a reference for phase difference detection in the column phase difference detection unit 70. The signal line 215 is commonly connected to one input terminals of the column phase difference detection units 70a, 70b, and 70c. The signal line H_OUT1, the signal line H_OUT2, and the signal line H_OUT3 are respectively connected to the other input terminals of the column phase difference detection units 70a, 70b, and 70c. A phase difference between the column drive signal and the reference signal is detected for each column by the column phase difference detection units 70a, 70b, and 70c. Output terminals of the column phase difference detection units 70a, 70b, and 70c are respectively connected to input terminals of column phase difference selection units 71a, 71b, and 71c to be described later.

Similarly to the row phase difference selection unit 61, the column phase difference selection unit 71 includes the column phase difference selection units 71a, 71b, and 71c including current output-type inverting buffers with control input terminals. In addition, a signal line 213 is connected to the column phase difference selection unit 71. Similarly to the signal line 211 described in FIG. 3, this signal line 213 includes three signal lines, each of which transmits the selection signal from the control unit 90. The signal lines 213 are individually connected to the control input terminals of the column phase difference selection units 71a, 71b, and 71c. The control unit 90 outputs the selection signal having the value “1” to the column phase difference selection units 71a, 71b, and 71c for a column to be selected, and outputs the value “0” to the column phase difference selection units 71a, 71b, and 71c for a column not to be selected. The column phase difference selection units 71a, 71b, and 71c to the control input terminal of which the selection signal having the value “1” is input invert the detection result of the column phase difference detection unit 70 and transmit the inverted detection result, and the column phase difference selection units 71a, 71b, and 71c to the control input terminal of which the value “0” is input have outputs in a high impedance state. As a result, selection of the detection result of the column phase difference detection unit 70 by the column phase difference selection units 71a, 71b, and 71c is performed.

Output terminals of the column phase difference selection units 71a, 71b, and 71c are commonly connected to one end of a capacitor 74 (not illustrated in FIG. 1) and an input of an analog-to-digital conversion unit 75 (not illustrated in FIG. 1). The other end of the capacitor 74 is grounded. Since the configurations of the capacitor 74 and the analog-to-digital conversion unit 75 are similar to those of the capacitor 64 and the analog-to-digital conversion unit 65 in FIG. 3, the description thereof will be omitted. The column delay adjustment unit 72 adjusts the delays of the column drive signal delay units 50a, 50b, and 50c on the basis of the input digital phase difference signal.

### [Configuration of Delay Circuit]

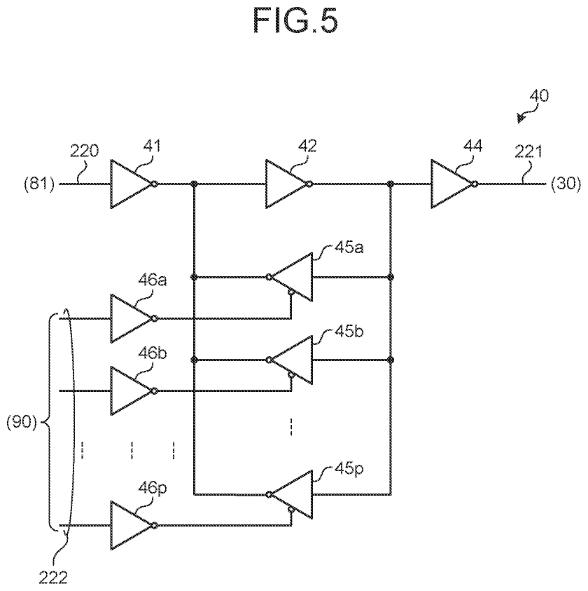

FIG. 5 is a diagram illustrating a configuration example of a row drive signal delay unit according to the embodiment of the present disclosure. The drawing is a circuit diagram illustrating a configuration example of the row drive signal delay unit 40. Note that a similar circuit can also be used for the column drive signal delay unit 50.

The row drive signal delay unit 40 in the drawing includes a logic circuit element 41, a delay element 42, buffer circuits 45a to 45p, inverting gates 46a to 45p, and an output buffer 44. The drawing represents an example of including 16 buffer circuits 45 and 16 inverting buffers 46. For the logic circuit element 41, for example, an inverting gate can be used. In addition, for the delay element 42, for example, an inverting gate can be used. In addition, for the buffer circuits 45a to 45p, for example, inverting buffers with control input terminals can be used.

The circuit in the drawing constitutes a delay circuit that causes a delay in a change in an input signal. In the drawing, a signal line 220 and a signal line 221 are respectively an input signal line and an output signal line. In addition, a signal line 222 includes 16 signal lines, to which a signal for setting a delay time is input. The signal line 220 is connected to an output of the row selection unit 81, and the signal line 221 is connected to an input of the row drive unit 30. In addition, the signal line 222 is connected to the output of the control unit 90.

The signal line 220 is connected to an input terminal of the logic circuit element 41. An output of the logic circuit element 41 is connected to an input terminal of the row drive signal delay unit 40 and output terminals of the buffer circuits 45a to 45p. An output terminal of the row drive signal delay unit 40 is connected to an input terminal of the output buffer 44 and input terminals of the buffer circuits 45a to 45p. An output terminal of the output buffer 44 is connected to the signal line 221. The 16 signal lines of the signal line 222 are respectively connected to input terminals of the inverting gates 46a to 45p. Output terminals of the inverting gates 46a to 45p are respectively connected to the control input terminals of the buffer circuits 45a to 45p.

A signal delayed by the delay element 42 is added to the output of the logic circuit element 41 via the buffer circuits 45a to 45p. This signal is a signal obtained by transmitting an input signal of the row drive signal delay unit 40 by the logic circuit element 41 and the delay element 42, and is a signal based on the input signal. In a normal state, the output of the logic circuit element 41 and the outputs of the buffer circuits 45a to 45p are at the same logic level. On the other hand, in the transition of the output of the logic circuit element 41, the output of the logic circuit element 41 and the outputs of the buffer circuits 45a to 45p are at different logic levels due to the delays of the delay element 42 and the buffer circuits 45a to 45p. Therefore, a transition time of the output of the logic circuit element 41 is lengthened, and a propagation delay increases.

This propagation delay changes depending on the number of the buffer circuits 45a to 45p in an ON state. The maximum propagation delay is obtained when all the buffer circuits 45a to 45p are in the ON state, and the minimum propagation delay is obtained when all the outputs of the buffer circuits 45a to 45p are in the high impedance state. The delay time can be adjusted according to the number of signal lines from which a signal for bringing the buffer circuits 45a to 45p into the ON state is output in the plurality of signal lines of the signal line 222. Note that the logic circuit element 41 includes an output stage having a higher driving capability than the buffer circuits 45a to 45p.

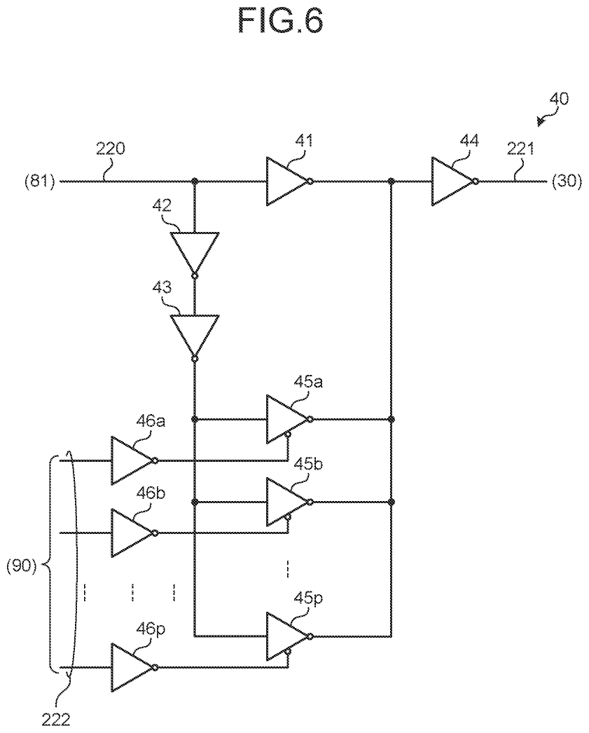

FIG. 6 is a diagram illustrating another configuration example of a row drive signal delay unit according to the embodiment of the present disclosure. The drawing is a circuit diagram illustrating another configuration example of the row drive signal delay unit 40. Note that a similar circuit can also be used for the column drive signal delay unit 50.

The row drive signal delay unit 40 in the drawing includes the logic circuit element 41, the delay element 42 and a delay element 43, the buffer circuits 45a to 45p, the inverting gates 46a to 45p, and the output buffer 44. The drawing also represents an example of including 16 buffer circuits 45 and 16 inverting buffers 46 similarly to the delay circuit of FIG. 5. For the delay elements 42 and 43, for example, inverting gates can be used.

The signal line 222 is connected to the input terminal of the logic circuit element 41 and an input terminal of the delay element 42. An output terminal of the delay element 42 is connected to an input terminal of the delay element 43. An output terminal of the delay element 43 is connected to the input terminals of the buffer circuits 45a to 45p. The output terminals of the buffer circuits 45a to 45p are connected to an output terminal of the logic circuit element 41 and the input terminal of the output buffer 44. An output terminal of the output buffer 44 is connected to the signal line 221. The 16 signal lines of the signal line 222 are respectively connected to input terminals of the inverting gates 46a to 45p. Output terminals of the inverting gates 46a to 45p are respectively connected to the control input terminals of the buffer circuits 45a to 45p.

In the circuit of the drawing, the input signal of the signal line 220 is added to the output of the logic circuit element 41 via the delay elements 42 and 43 and the buffer circuits 45a to 45p. Similarly to the delay circuit of FIG. 5, the delay time can be adjusted according to the number of signal lines from which a signal for bringing the buffer circuits 45a to 45p into the ON state is output in the plurality of signal lines of the signal line 222.

### [Driving of Light Emitting Element Array Unit]

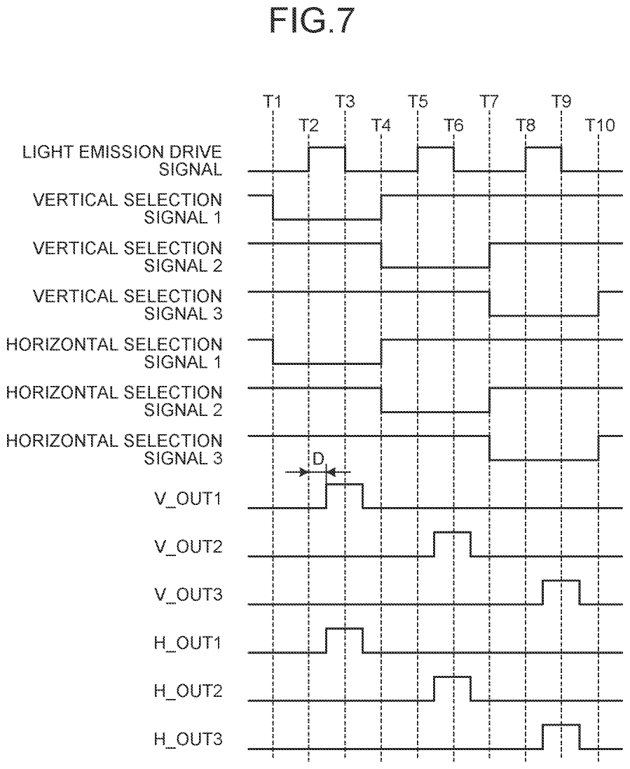

FIG. 7 is a diagram illustrating an example of a method of driving a light emitting element array unit according to the embodiment of the present disclosure. The drawing is a timing chart representing an example of a method of driving the light emitting element array unit 10 in the light source device 1. In the drawing, “LIGHT EMISSION DRIVE SIGNAL” represents a waveform of the light emission drive signal described in FIG. 1. “VERTICAL SELECTION SIGNAL” and “HORIZONTAL SELECTION SIGNAL” respectively represent waveforms of the vertical selection signal input to the row selection unit 81 and the horizontal selection signal input to the column selection unit 82. Note that the numbers at the end of “VERTICAL SELECTION SIGNAL” and “HORIZONTAL SELECTION SIGNAL” represent the corresponding row and column of the light emitting element array unit 10. “V_OUT1”, “V_OUT2”, “V_OUT3”, “H_OUT1”, “H_OUT2”, and “H_OUT3” respectively represent waveforms of the signal line V_OUT1, the signal line V_OUT2, the signal line V_OUT3, the signal line H_OUT1, the signal line H_OUT2, and the signal line H_OUT3 described in FIG. 2.

Note that the drawing represents an example of a case where the light emitting elements 11 in the first row and first column, the second row and second column, and the third row and third column of the light emitting element array unit 10 are caused to sequentially emit light.

At T1, the value “0” is output to the vertical selection signal 1 and the horizontal selection signal 1, and the first row and the first column of the light emitting element array unit 10 are selected. Note that the output of the value “0” of the vertical selection signal 1 and the horizontal selection signal 1 continues until T4.

At T2, the value “1” is input as the light emission drive signal. The row drive signal delay unit 40 generates a row drive signal delayed with respect to this light emission drive signal. This generated row drive signal is input to the row drive unit 30 to generate a drive signal, and the drive signal is output to the signal line V_OUT1. As a result, the row light emission drive unit 20 of the light emitting element array unit 10 is conducted. In addition, the column drive signal delay unit 50 generates a column drive signal delayed with respect to the light emission drive signal. This generated column drive signal is input to the column drive unit 33 to generate a drive signal, and the drive signal is output to the signal line H_OUT1. As a result, the column light emission drive unit 23 of the light emitting element array unit 10 is conducted. A light emission current flows to the light emitting element 11 in the first row and first column of the light emitting element array unit 10 to cause light emission.

The drive signal output to the signal line V_OUT1 is a signal delayed with respect to the light emission drive signal due to the delay of the row drive signal delay unit 40 or the like. “D” in the drawing represents this delay time.

At T3, the input of the light emission drive signal having the value “1” is stopped. After the delay time elapses, the output of the drive signal to the signal line V_OUT1 and the signal line H_OUT1 is stopped, and the row light emission drive unit 20 and the column light emission drive unit 23 of the light emitting element array unit 10 return to a non-conductive state. Therefore, the light emission of the light emitting element 11 is stopped.

At T4, the output of the value “0” to the vertical selection signal 1 and the horizontal selection signal 1 is stopped. In addition, the value “0” is output to the vertical selection signal 2 and the horizontal selection signal 2.

At T5, the value “1” is input as the light emission drive signal, and the drive signal is output to the signal line V_OUT2 and the signal line H_OUT2 after the delay time elapses. As a result, the row light emission drive unit 21 and the column light emission drive unit 24 are conducted, and the light emitting element 11 in the second row and second column of the light emitting element array unit 10 emits light.

At T6, the input of the light emission drive signal having the value “1” is stopped. After the delay time elapses, the output of the drive signal to the signal line V_OUT2 and the signal line H_OUT2 is stopped, the row light emission drive unit 21 and the column light emission drive unit 24 of the light emitting element array unit 10 return to the non-conductive state, and the light emission of the light emitting element 11 is stopped.

At T7, the output of the value “0” to the vertical selection signal 2 and the horizontal selection signal 2 is stopped. In addition, the value “0” is output to the vertical selection signal 3 and the horizontal selection signal 3.

At T8, the value “1” is input as the light emission drive signal, and the drive signal is output to the signal line V_OUT3 and the signal line H_OUT3 after the delay time elapses. As a result, the row light emission drive unit 22 and the column light emission drive unit 25 are conducted, and the light emitting element 11 in the third row and third column of the light emitting element array unit 10 emits light.

At T9, the input of the light emission drive signal having the value “1” is stopped. After the delay time elapses, the output of the drive signal to the signal line V_OUT3 and the signal line H_OUT3 is stopped, the row light emission drive unit 22 and the column light emission drive unit 25 of the light emitting element array unit 10 return to the non-conductive state, and the light emission of the light emitting element 11 is stopped.

At T10, the output of the value “0” to the vertical selection signal 3 and the horizontal selection signal 3 is stopped. Through the above procedure, the light emitting elements 11 of the light emitting element array unit 10 can be caused to emit light.

Note that the configuration of the light source device 1 is not limited to this example. For example, it is also possible to adopt a configuration in which the row phase difference detection unit 60 detects a phase difference on the basis of output signals of the row light emission drive units 20 and the like. Similarly, it is also possible to adopt a configuration in which the column phase difference detection unit 70 detects a phase difference on the basis of output signals of the column light emission drive units 23 and the like. In addition, it is also possible to adopt a configuration in which the row phase difference selection unit 61 selects the row drive signal of the row drive units 30 to 32, and the row phase difference detection unit 60 detects a phase difference of the row drive signal selected by the row phase difference selection unit 61. Similarly, it is also possible to adopt a configuration in which the column phase difference selection unit 71 selects the column drive signal of the column drive units 33 to 35, and the column phase difference detection unit 70 detects a phase difference of the column drive signal selected by the column phase difference selection unit 71.

As described above, the light source device 1 of the present disclosure includes the light emitting element array unit 10 in which the plurality of light emitting elements 11 is arranged in a two-dimensional matrix. For this light emitting element array unit 10, the row light emission drive units 20 to 22 are arranged for respective rows, the column light emission drive units 23 to 25 are arranged for respective columns, and the light emitting element array unit 10 is driven for each row and column. The delays of the row light emission drive units 20 to 22 and the column light emission drive units 23 to 25 are each individually adjusted. As a result, the delay time of light emission of the light emitting element 11 in the light emitting element array unit 10 can be adjusted, and variation in light emission delay can be reduced. A circuit for delay adjustment can be simplified as compared with a case where the respective light emitting elements 11 of the light emitting element array unit 10 are individually driven and the delay times are individually adjusted.

### 2. Second Embodiment

The light source device 1 of the first embodiment described above includes the plurality of row drive signal delay units 40 and the plurality of column drive signal delay units 50. On the other hand, a light source device 1 according to a second embodiment of the present disclosure is different from that of the first embodiment described above in that a delay of a light emission drive signal is adjusted.

### [Configuration of Light Source Device]

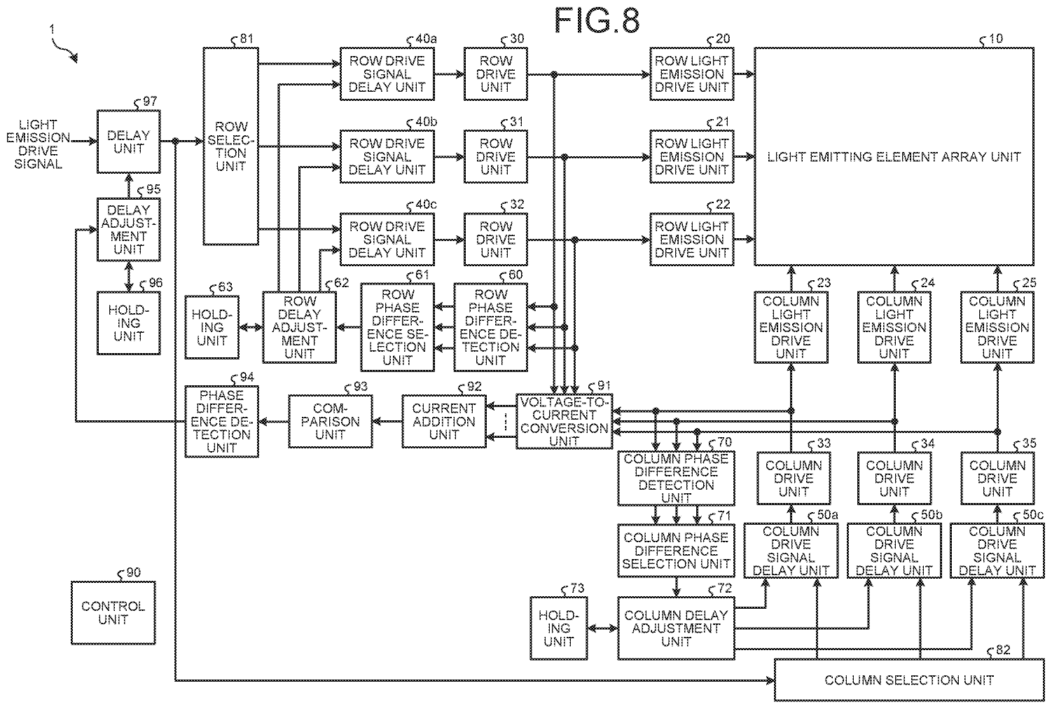

FIG. 8 is a diagram illustrating a configuration example of the light source device according to the second embodiment of the present disclosure. The drawing is a block diagram illustrating a configuration example of the light source device 1 similarly to FIG. 1. The light source device 1 of FIG. 8 is different from the light source device 1 of FIG. 1 in further including a voltage-to-current conversion unit 91, a current addition unit 92, a comparison unit 93, a phase difference detection unit 94, a delay adjustment unit 95, a delay unit 97, and a holding unit 96.

The delay unit 97 delays the light emission drive signal. The delayed light emission drive signal is output to a row selection unit 81 and a column selection unit 82. A delay time of the delay unit 97 is adjusted by the delay adjustment unit 95. Note that the delay unit 97 is an example of a light emission drive signal delay unit described in the claims.

The voltage-to-current conversion unit 91 converts row drive signals of row drive units 30 to 32 and column drive signals of column drive units 33 to 35 into current signals. The converted current signals are output to the current addition unit 92.

The current addition unit 92 adds the row drive signal and the column drive signal converted into the current signals by the voltage-to-current conversion unit 91. The added current signal is output to the comparison unit 93.

The comparison unit 93 compares the current signal output from the current addition unit 92 with a predetermined threshold, and outputs a comparison result. As the threshold, a current value of ½ of the total value of all the row drive signals and all the column drive signals can be used. As a result, a signal of the comparison result becomes a signal of an average timing of all the row drive signals and all the column drive signals, and becomes a signal of an average delay time of all the row drive signals and all the column drive signals. This signal is output to the phase difference detection unit 94.

The phase difference detection unit 94 detects the comparison result of the comparison unit 93, that is, a phase difference between the signal of the average delay time of the row drive signals and the column drive signals and a reference signal. The detection result of the phase difference is output to the delay adjustment unit 95.

The delay adjustment unit 95 adjusts a delay time of the delay unit 97 on the basis of the detection result of the phase difference output from the phase difference detection unit 94. By arranging the delay adjustment unit 95 to adjust the delay of the light emission drive signal in the delay unit 97, it is possible to reduce variation in the delay time of light emission of the light emitting element 11 based on a change in an operating environment or the like. Information on the adjusted delay is held in the holding unit 96. Note that the delay adjustment unit 95 is an example of a light emission drive signal delay adjustment unit described in the claims.

The configuration of the light source device 1 other than this is similar to the configuration of the light source device 1 in the first embodiment of the present disclosure, and thus the description thereof will be omitted.

As described above, the light source device 1 according to the second embodiment of the present disclosure adjusts the delay time of the light emission drive signal using the signal of the average delay time of the plurality of row drive signals and the plurality of row drive signals. As a result, it is possible to reduce variation in delay in light emission of the light emitting element 11 based on a change in an operating environment or the like.

### 3. Configuration Example of Imaging Device

### [Configuration of Imaging Device]

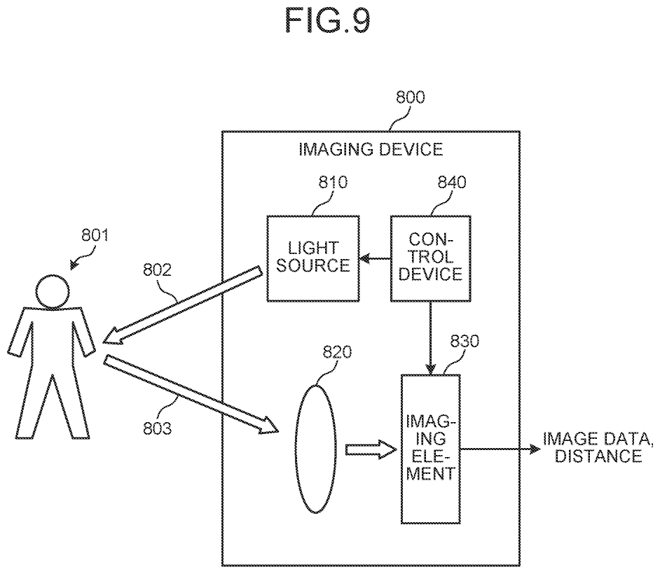

FIG. 9 is a diagram illustrating a configuration example of an imaging device to which the technology according to the present disclosure can be applied. The drawing is a block diagram representing a configuration example of an imaging device 800. The imaging device 800 includes an imaging element 830, a control device 840, a light source 810, and an imaging lens 820. This imaging device 800 performs imaging of a subject and also performs distance measurement for measuring a distance to the subject. The imaging device 800 outputs image data of the subject generated by imaging and a distance to an object that is the subject to be subjected to distance measurement. An object 801 is further illustrated in the drawing.

The imaging element 830 is a semiconductor element that performs imaging of a subject. In addition, this imaging element 830 performs distance measurement on the imaged subject. The imaging element 830 includes a plurality of pixels that performs photoelectric conversion of incident light from the subject to generate an image signal.

The light source 810 applies light. This light source 810 applies outgoing light 802 to the object 801 in distance measurement. As the light source 810, for example, a light emitting diode or a laser diode that outputs infrared light can be used.

The imaging lens 820 is a lens that forms an image of a subject on a light receiving surface that is a surface on which the pixels of the imaging element 830 are arranged.

The control device 840 controls the whole of the imaging device 800. In distance measurement, this control device 840 controls the light source 810 to output the outgoing light 802 and controls the imaging element 830 to perform imaging and distance measurement.

In distance measurement, the outgoing light 802 is reflected by the object 801, and reflected light 803 is generated. This reflected light 803 is incident on the imaging element 830 via the imaging lens 820 and is detected. In addition, a time from the output of the outgoing light 802 in the light source 810 to the detection of the reflected light 803 in the imaging element 830 is counted by the imaging element 830, and the distance to the object 801 is calculated.

An example of the imaging device to which the technology according to the present disclosure can be applied has been described above. The technology according to the present disclosure can be applied to the light source 810 in the configurations described above. Specifically, the light source device 1 of FIG. 1 can be applied to the light source 810.

### Effects

A drive circuit includes: a plurality of row drive signal delay units 40 and the like arranged for respective rows in a light emitting element array unit 10, the light emitting element array unit 10 being configured by arranging a plurality of light emitting elements 11 in the form of a two-dimensional matrix, the plurality of light emitting elements 11 emitting light by a flow of a light emission current, the plurality of row drive signal delay units 40 and the like outputting a row drive signal obtained by delaying a light emission drive signal for controlling light emission of the light emitting element 11; a plurality of column drive signal delay units 50 and the like arranged for respective columns in the light emitting element array unit 10, the plurality of column drive signal delay units 50 and the like outputting a column drive signal obtained by delaying the light emission drive signal; a plurality of row light emission drive units 20 and the like arranged for the respective rows in the light emitting element array unit 10, the plurality of row light emission drive units 20 and the like supplying, on the basis of the row drive signal output by the row drive signal delay unit 40 or the like arranged for the row, the light emission current as a source current to a plurality of the light emitting elements 11 arranged in the row; a plurality of column light emission drive units 23 and the like arranged for the respective columns in the light emitting element array unit 10, the plurality of column light emission drive units 23 and the like supplying, on the basis of the column drive signal output by the column drive signal delay unit 50 or the like arranged for the column, the light emission current as a sink current to a plurality of the light emitting elements 11 arranged in the column; a row delay adjustment unit 62 adjusting a delay time in the plurality of row drive signal delay units 40 and the like; and a column delay adjustment unit 72 adjusting a delay time in the plurality of column drive signal delay units 50 and the like. As a result, a delay in light emission of the light emitting elements 11 of the light emitting element array unit 10 can be adjusted for each row and column.

In addition, the drive circuit may further include: a row phase difference detection unit 60 detecting phase differences between a plurality of the row drive signals and a reference signal; and a column phase difference detection unit 70 detecting phase differences between a plurality of the column drive signals and the reference signal, in which the row delay adjustment unit 62 may adjust the delay time on the basis of a detection result of the row phase difference detection unit 60, and the column delay adjustment unit 72 may adjust the delay time on the basis of a detection result of the column phase difference detection unit 70.

In addition, the row phase difference detection unit 60 may be arranged for each of the plurality of row drive signal delay units 40 and the like and detect the phase difference in the corresponding row drive signal delay unit 40 or the like, the column phase difference detection unit 70 may be arranged for each of the plurality of column drive signal delay units 50 and the like and detect the phase difference in the corresponding column drive signal delay unit 50 or the like, the row delay adjustment unit 62 may adjust the delay time of the corresponding row drive signal delay unit 40 or the like on the basis of the detection result of each of a plurality of the row phase difference detection units 60, and the column delay adjustment unit 72 may adjust the delay time of the corresponding column drive signal delay unit 50 or the like on the basis of the detection result of each of a plurality of the column phase difference detection units 70.

In addition, the drive circuit may further include: a plurality of row drive units respectively arranged for the plurality of row light emission drive units 20 and the like and each driving the row light emission drive unit 20 or the like on the basis of the row drive signal; and a plurality of column drive units respectively arranged for the plurality of column light emission drive units 23 and the like and each driving the column light emission drive unit 23 or the like on the basis of the column drive signal; in which a plurality of the row phase difference detection units 60 may detect the phase difference on the basis of output signals of the plurality of row drive units, and a plurality of the column phase difference detection units 70 may detect the phase difference on the basis of output signals of the plurality of column drive units.

In addition, a plurality of the row phase difference detection units 60 may detect the phase difference on the basis of output signals of the plurality of row light emission drive units 20 and the like, and a plurality of the column phase difference detection units 70 may detect the phase difference on the basis of output signals of the plurality of column light emission drive units 23 and the like.

In addition, the drive circuit may further include: a delay unit 97 delaying the light emission drive signal and outputting the delayed light emission activation signal to the plurality of row drive signal delay units 40 and the like and the plurality of column drive signal delay units 50 and the like; and a delay adjustment unit 95 adjusting a delay time in the delay unit 97. As a result, the delay of the light emission drive signal can be adjusted.

In addition, the delay adjustment unit 95 may adjust the delay time on the basis of phase differences between a plurality of the row drive signals and a plurality of the column drive signals, and a reference delay signal.

In addition, the delay adjustment unit 95 may adjust the delay time on the basis of a phase difference between a signal of an average delay time in the plurality of row drive signals and the plurality of column drive signals and the reference delay signal.

A light source device includes: a light emitting element array unit 10 configured by arranging a plurality of light emitting elements 11 in the form of a two-dimensional matrix, the plurality of light emitting elements 11 emitting light by a flow of a light emission current; a plurality of row drive signal delay units 40 and the like arranged for respective rows in the light emitting element array unit 10, the plurality of row drive signal delay units 40 and the like outputting a row drive signal obtained by delaying a light emission drive signal for controlling light emission of the light emitting element 11; a plurality of column drive signal delay units 50 and the like arranged for respective columns in the light emitting element array unit 10, the plurality of column drive signal delay units 50 and the like outputting a column drive signal obtained by delaying the light emission drive signal; a plurality of row light emission drive units 20 and the like arranged for the respective rows in the light emitting element array unit 10, the plurality of row light emission drive units 20 and the like supplying, on the basis of the row drive signal output by the row drive signal delay unit 40 or the like arranged for the row, the light emission current as a source current to a plurality of the light emitting elements 11 arranged in the row; a plurality of column light emission drive units 23 and the like arranged for the respective columns in the light emitting element array unit 10, the plurality of column light emission drive units 23 and the like supplying, on the basis of the column drive signal output by the column drive signal delay unit 50 or the like arranged for the column, the light emission current as a sink current to a plurality of the light emitting elements 11 arranged in the column; a row delay adjustment unit 62 adjusting a delay time in the plurality of row drive signal delay units 40 and the like; and a column delay adjustment unit 72 adjusting a delay time in the plurality of column drive signal delay units 50 and the like. The delay in light emission of the light emitting elements 11 of the light emitting element array unit 10 can be adjusted for each row and column.

A delay circuit causing a delay in a change in an output signal with respect to a change in an input signal, the delay circuit including: a logic circuit element receiving the input signal; a delay element delaying the input signal; and a plurality of buffer circuits including a control input terminal for receiving a control signal for bringing an output terminal into a high impedance state, the plurality of buffer circuits receiving the input signal delayed by the delay element, the output terminal being connected to an output node of the logic circuit element, in which the delay circuit adjusts the delay by extracting a signal of the output node of the logic circuit element as a delay signal and adjusting the control signal to be input to the plurality of buffer circuits. A delay time can be finely adjusted by the plurality of buffer circuits. In addition, a delay inherent in the delay circuit can be shortened.

In addition, the delay element may have an input terminal connected to the output node of the logic circuit element, delay a signal transmitted via the logic circuit element as the input signal, and output the delayed signal as the delay signal.

Note that the effects described in the present specification are merely examples and are not limited, and other effects may be provided.

Note that the present technology can also have the following configurations.

(1)

A drive circuit comprising:
a plurality of row drive signal delay units arranged for respective rows in a light emitting element array unit, the light emitting element array unit being configured by arranging a plurality of light emitting elements in a form of a two-dimensional matrix, the plurality of light emitting elements emitting light by a flow of a light emission current, the plurality of row drive signal delay units outputting a row drive signal obtained by delaying a light emission drive signal for controlling light emission of the light emitting element;
a plurality of column drive signal delay units arranged for respective columns in the light emitting element array unit, the plurality of column drive signal delay units outputting a column drive signal obtained by delaying the light emission drive signal;
a plurality of row light emission drive units arranged for the respective rows in the light emitting element array unit, the plurality of row light emission drive units supplying, on a basis of the row drive signal output by the row drive signal delay unit arranged for the row, the light emission current as a source current to a plurality of the light emitting elements arranged in the row;
a plurality of column light emission drive units arranged for the respective columns in the light emitting element array unit, the plurality of column light emission drive units supplying, on a basis of the column drive signal output by the column drive signal delay unit arranged for the column, the light emission current as a sink current to a plurality of the light emitting elements arranged in the column;
a row delay adjustment unit adjusting a delay time in the plurality of row drive signal delay units; and a column delay adjustment unit adjusting a delay time in the plurality of column drive signal delay units.
   (2) The drive circuit according to the above (1), further comprising:
a row phase difference detection unit detecting phase differences between a plurality of the row drive signals and a reference signal; and
a column phase difference detection unit detecting phase differences between a plurality of the column drive signals and the reference signal, wherein
the row delay adjustment unit adjusts the delay time on a basis of a detection result of the row phase difference detection unit, and
the column delay adjustment unit adjusts the delay time on a basis of a detection result of the column phase difference detection unit.
   (3)

The drive circuit according to the above (2), wherein
the row phase difference detection unit is arranged for each of the plurality of row drive signal delay units and detects the phase difference in the corresponding row drive signal delay unit,
the column phase difference detection unit is arranged for each of the plurality of column drive signal delay units and detects the phase difference in the corresponding column drive signal delay unit,
the row delay adjustment unit adjusts the delay time of the corresponding row drive signal delay unit on a basis of the detection result of each of a plurality of the row phase difference detection units, and
the column delay adjustment unit adjusts the delay time of the corresponding column drive signal delay unit on a basis of the detection result of each of a plurality of the column phase difference detection units.
   (4)

The drive circuit according to the above (2), further comprising:
a plurality of row drive units respectively arranged for the plurality of row light emission drive units and each driving the row light emission drive unit on a basis of the row drive signal; and
a plurality of column drive units respectively arranged for the plurality of column light emission drive units and each driving the column light emission drive unit on a basis of the column drive signal, wherein
a plurality of the row phase difference detection units detects the phase difference on a basis of output signals of the plurality of row drive units, and
a plurality of the column phase difference detection units detects the phase difference on a basis of output signals of the plurality of column drive units.
   (5)

The drive circuit according to the above (2), wherein
a plurality of the row phase difference detection units detects the phase difference on a basis of output signals of the plurality of row light emission drive units, and
a plurality of the column phase difference detection units detects the phase difference on a basis of output signals of the plurality of column light emission drive units.
   (6)

The drive circuit according to any one of the above (1) to (5), further comprising:
a light emission drive signal delay unit delaying the light emission drive signal and outputting the delayed light emission drive signal to the plurality of row drive signal delay units and the plurality of column drive signal delay units; and
a light emission drive signal delay adjustment unit adjusting a delay time in the light emission drive signal delay unit.
   (7)

The drive circuit according to the above (6), wherein
the light emission drive signal delay adjustment unit adjusts the delay time on a basis of phase differences between a plurality of the row drive signals and a plurality of the column drive signals, and a reference delay signal.
   (8)

The drive circuit according to the above (7), wherein
the light emission drive signal delay adjustment unit adjusts the delay time on a basis of a phase difference between a signal of an average delay time in the plurality of row drive signals and the plurality of column drive signals and the reference delay signal.
   (9)

A light source device comprising:
a light emitting element array unit configured by arranging a plurality of light emitting elements in a form of a two-dimensional matrix, the plurality of light emitting elements emitting light by a flow of a light emission current;
a plurality of row drive signal delay units arranged for respective rows in the light emitting element array unit, the plurality of row drive signal delay units outputting a row drive signal obtained by delaying a light emission drive signal for controlling light emission of the light emitting element;
a plurality of column drive signal delay units arranged for respective columns in the light emitting element array unit, the plurality of column drive signal delay units outputting a column drive signal obtained by delaying the light emission drive signal;
a plurality of row light emission drive units arranged for the respective rows in the light emitting element array unit, the plurality of row light emission drive units supplying, on a basis of the row drive signal output by the row drive signal delay unit arranged for the row, the light emission current as a source current to a plurality of the light emitting elements arranged in the row;
a plurality of column light emission drive units arranged for the respective columns in the light emitting element array unit, the plurality of column light emission drive units supplying, on a basis of the column drive signal output by the column drive signal delay unit arranged for the column, the light emission current as a sink current to a plurality of the light emitting elements arranged in the column;
a row delay adjustment unit adjusting a delay time in the plurality of row drive signal delay units; and
a column delay adjustment unit adjusting a delay time in the plurality of column drive signal delay units.
   (10)

A delay circuit causing a delay in a change in an output signal with respect to a change in an input signal, the delay circuit comprising:
a logic circuit element receiving the input signal;
a delay element delaying the input signal; and
a plurality of buffer circuits including a control input terminal for receiving a control signal for bringing an output terminal into a high impedance state, the plurality of buffer circuits receiving the input signal delayed by the delay element, the output terminal being connected to an output node of the logic circuit element, wherein
the delay circuit adjusts the delay by extracting a signal of the output node of the logic circuit element as a delay signal and adjusting the control signal to be input to the plurality of buffer circuits.
   (11)

The delay circuit according to the above (10), wherein,
the delay element has an input terminal connected to the output node of the logic circuit element, delays a signal transmitted via the logic circuit element as the input signal, and outputs the delayed signal as the delay signal.

### REFERENCE SIGNS LIST

1 LIGHT SOURCE DEVICE
10 LIGHT EMITTING ELEMENT ARRAY UNIT
11 LIGHT EMITTING ELEMENT
20 to 22 ROW LIGHT EMISSION DRIVE UNIT
23 to 25 COLUMN LIGHT EMISSION DRIVE UNIT
30 to 32 ROW DRIVE UNIT
33 to 35 COLUMN DRIVE UNIT
40, 40a, 40b, 40c ROW DRIVE SIGNAL DELAY UNIT
50, 50a, 50b, 50c COLUMN DRIVE SIGNAL DELAY UNIT
60, 60a, 60b, 60c ROW PHASE DIFFERENCE DETECTION UNIT
61, 61a, 61b, 61c ROW PHASE DIFFERENCE SELECTION UNIT
62 ROW DELAY ADJUSTMENT UNIT
63, 73, 96 HOLDING UNIT
70, 70a, 70b, 70c COLUMN PHASE DIFFERENCE DETECTION UNIT
71, 71a, 71b, 71c COLUMN PHASE DIFFERENCE SELECTION UNIT
72 COLUMN DELAY ADJUSTMENT UNIT
81, 81a, 81b, 81c ROW SELECTION UNIT
82, 82a, 82b, 82c COLUMN SELECTION UNIT
91 VOLTAGE-TO-CURRENT CONVERSION UNIT
92 CURRENT ADDITION UNIT
93 COMPARISON UNIT
94 PHASE DIFFERENCE DETECTION UNIT
95 DELAY ADJUSTMENT UNIT
97 DELAY UNIT
800 IMAGING DEVICE
810 LIGHT SOURCE

1. A drive circuit comprising:
a plurality of row drive signal delay units arranged for respective rows in a light emitting element array unit, the light emitting element array unit being configured by arranging a plurality of light emitting elements in a form of a two-dimensional matrix, the plurality of light emitting elements emitting light by a flow of a light emission current, the plurality of row drive signal delay units outputting a row drive signal obtained by delaying a light emission drive signal for controlling light emission of the light emitting element;
a plurality of column drive signal delay units arranged for respective columns in the light emitting element array unit, the plurality of column drive signal delay units outputting a column drive signal obtained by delaying the light emission drive signal;
a plurality of row light emission drive units arranged for the respective rows in the light emitting element array unit, the plurality of row light emission drive units supplying, on a basis of the row drive signal output by the row drive signal delay unit arranged for the row, the light emission current as a source current to a plurality of the light emitting elements arranged in the row;
a plurality of column light emission drive units arranged for the respective columns in the light emitting element array unit, the plurality of column light emission drive units supplying, on a basis of the column drive signal output by the column drive signal delay unit arranged for the column, the light emission current as a sink current to a plurality of the light emitting elements arranged in the column;
a row delay adjustment unit adjusting a delay time in the plurality of row drive signal delay units; and
a column delay adjustment unit adjusting a delay time in the plurality of column drive signal delay units.

2. The drive circuit according to claim 1, further comprising:
a row phase difference detection unit detecting phase differences between a plurality of the row drive signals and a reference signal; and
a column phase difference detection unit detecting phase differences between a plurality of the column drive signals and the reference signal, wherein
the row delay adjustment unit adjusts the delay time on a basis of a detection result of the row phase difference detection unit, and
the column delay adjustment unit adjusts the delay time on a basis of a detection result of the column phase difference detection unit.

3. The drive circuit according to claim 2, wherein
the row phase difference detection unit is arranged for each of the plurality of row drive signal delay units and detects the phase difference in the corresponding row drive signal delay unit,
the column phase difference detection unit is arranged for each of the plurality of column drive signal delay units and detects the phase difference in the corresponding column drive signal delay unit,
the row delay adjustment unit adjusts the delay time of the corresponding row drive signal delay unit on a basis of the detection result of each of a plurality of the row phase difference detection units, and
the column delay adjustment unit adjusts the delay time of the corresponding column drive signal delay unit on a basis of the detection result of each of a plurality of the column phase difference detection units.

4. The drive circuit according to claim 2, further comprising:
a plurality of row drive units respectively arranged for the plurality of row light emission drive units and each driving the row light emission drive unit on a basis of the row drive signal; and
a plurality of column drive units respectively arranged for the plurality of column light emission drive units and each driving the column light emission drive unit on a basis of the column drive signal, wherein
a plurality of the row phase difference detection units detects the phase difference on a basis of output signals of the plurality of row drive units, and
a plurality of the column phase difference detection units detects the phase difference on a basis of output signals of the plurality of column drive units.

5. The drive circuit according to claim 2, wherein
a plurality of the row phase difference detection units detects the phase difference on a basis of output signals of the plurality of row light emission drive units, and
a plurality of the column phase difference detection units detects the phase difference on a basis of output signals of the plurality of column light emission drive units.

6. The drive circuit according to claim 1, further comprising:
a light emission drive signal delay unit delaying the light emission drive signal and outputting the delayed light emission drive signal to the plurality of row drive signal delay units and the plurality of column drive signal delay units; and
a light emission drive signal delay adjustment unit adjusting a delay time in the light emission drive signal delay unit.

7. The drive circuit according to claim 6, wherein
the light emission drive signal delay adjustment unit adjusts the delay time on a basis of phase differences between a plurality of the row drive signals and a plurality of the column drive signals, and a reference delay signal.

8. The drive circuit according to claim 7, wherein
the light emission drive signal delay adjustment unit adjusts the delay time on a basis of a phase difference between a signal of an average delay time in the plurality of row drive signals and the plurality of column drive signals and the reference delay signal.

9. A light source device comprising:
a light emitting element array unit configured by arranging a plurality of light emitting elements in a form of a two-dimensional matrix, the plurality of light emitting elements emitting light by a flow of a light emission current;
a plurality of row drive signal delay units arranged for respective rows in the light emitting element array unit, the plurality of row drive signal delay units outputting a row drive signal obtained by delaying a light emission drive signal for controlling light emission of the light emitting element;
a plurality of column drive signal delay units arranged for respective columns in the light emitting element array unit, the plurality of column drive signal delay units outputting a column drive signal obtained by delaying the light emission drive signal;
a plurality of row light emission drive units arranged for the respective rows in the light emitting element array unit, the plurality of row light emission drive units supplying, on a basis of the row drive signal output by the row drive signal delay unit arranged for the row, the light emission current as a source current to a plurality of the light emitting elements arranged in the row;
a plurality of column light emission drive units arranged for the respective columns in the light emitting element array unit, the plurality of column light emission drive units supplying, on a basis of the column drive signal output by the column drive signal delay unit arranged for the column, the light emission current as a sink current to a plurality of the light emitting elements arranged in the column;
a row delay adjustment unit adjusting a delay time in the plurality of row drive signal delay units; and
a column delay adjustment unit adjusting a delay time in the plurality of column drive signal delay units.

10. A delay circuit causing a delay in a change in an output signal with respect to a change in an input signal, the delay circuit comprising:
a logic circuit element receiving the input signal;
a delay element delaying the input signal; and
a plurality of buffer circuits including a control input terminal for receiving a control signal for bringing an output terminal into a high impedance state, the plurality of buffer circuits receiving the input signal delayed by the delay element, the output terminal being connected to an output node of the logic circuit element, wherein
the delay circuit adjusts the delay by extracting a signal of the output node of the logic circuit element as a delay signal and adjusting the control signal to be input to the plurality of buffer circuits.

11. The delay circuit according to claim 10, wherein,
the delay element has an input terminal connected to the output node of the logic circuit element, delays a signal transmitted via the logic circuit element as the input signal, and outputs the delayed signal as the delay signal.
